(19) United States
(12) Patent Application Publication
(10) Pub. No.: US 2014/0112062 A1
(43) Pub. Date: Apr. 24, 2014

(54) METHOD AND SYSTEM FOR AN ADAPTIVE NEGATIVE-BOOST WRITE ASSIST CIRCUIT FOR MEMORY ARCHITECTURES

(71) Applicant: LSI CORPORATION, Milpitas, CA (US)

(72) Inventors: Manish Trivedi, Bangalore (IN); Ankur Goel, Bangalore (IN); Setti Shanmukheswara Rao, Bangalore (IN)

(73) Assignee: LSI CORPORATION, Milpitas, CA (US)

(21) Appl. No.: 13/657,919

(22) Filed: Oct. 23, 2012

(51) Int. Cl. G11C 11/00

(52) U.S. Cl. 365/154

(57) ABSTRACT

Disclosed is an adaptive negative bit-line boost write assist technique in which coupling capacitance scales with the number of rows and thereby maintains a constant negative bit-line level. The change in the coupling capacitance in neighboring signals as the height increases is utilized. The change is utilized for negative bit-line voltage generation.

### BACKGROUND OF THE INVENTION

In deep submicron technology nodes, increased process variation and device reliability issues place challenges in low power SRAM design. SRAMs occupy up to or more than 70% of the SoC area and therefore, SRAM area, power, performance and leakage are significant deciding factors in overall budgeting of SoC. With an ever increasing SRAM usage, and SRAM complexity, system level requirements are imposing increasing constraints on SRAM designs for improving key parameters like area, speed, leakage, dynamic power, etc. A unique feature of SRAMs, such as a 6 transistor SRAM, is an inherent trade-off between stability when holding data during a read or non-column selected write access and the ability of the cell to be written. This means that device dimensions and threshold voltage targets established for SRAM devices are compromise by design. The ability to read and write is characterized in terms of margins to assess the functional implications. It is difficult to design SRAM cells which are stable for both read and write without a large area overhead in SRAM cell size. Accordingly, an often used methodology is to make the cell stable for read by making pass-gate strength small and use a write-assist technique for write robustness. One other requirement on write ability of SRAMs is to write proper data in SRAM cells within the specified time.

### SUMMARY OF THE INVENTION

An embodiment of the invention may therefore comprise a method of producing capacitive coupling in a memory architecture, the memory architecture comprising a plurality of bitcell rows and bitcell columns and at least one layer, the method comprising placing at least one pair of metal lines over the rows of bitcells in an upper metal layer of the memory architecture wherein the metal lines produces a negative boost to bitlines in the memory architecture.

An embodiment of the invention may further comprise a system of producing capacitive coupling in a memory architecture, said system comprising a MUX select signal, an input data signal, a BOOST signal, a selected bitline, a write common node and a boost capacitor, wherein a write passgate turns on in response to the MUX select and input data signal, the boost signal is asserted high to discharge the bitline and write common node, and when it is determined that the bitline and write common node have been discharged to a Vss level, the boost signal is asserted low to produce capacitive coupling on the selected bitline and write common node with the boost capacitor.

### BRIEF DESCRIPTION OF THE DRAWINGS

FIG. 1 is a capacitive coupling boost capacitor.

FIG. 2 is a layout implementation of a capacitive coupling boost capacitor.

FIG. 3 shows a circuit implementation of a negative boost diagram.

FIG. 4 is a timing diagram showing write driver correspondence to bit-line BL0 assertion in response to Wsel0 and Din signal.

### DETAILED DESCRIPTION OF THE EMBODIMENTS

The design of SRAM cells has traditionally involved a compromise between the read and write functions of the memory array to maintain cell stability, read performance and write performance. In particular, the transistors which make up the cross-coupled latch must be weak enough to be overdriven during a write operation, while also strong enough to maintain their data value when driving a bit-line during a read operation. The access transistors that connect the cross-coupled inverters to the true and complement bit-lines affect both the stability and performance of the cell. It is understood that while the description of the invention may refer to SRAM type memories, the invention is not limited to SRAM. The techniques, methods and systems disclosed herein are equally applicable to other memory types, such as CAM and other memory architectures.

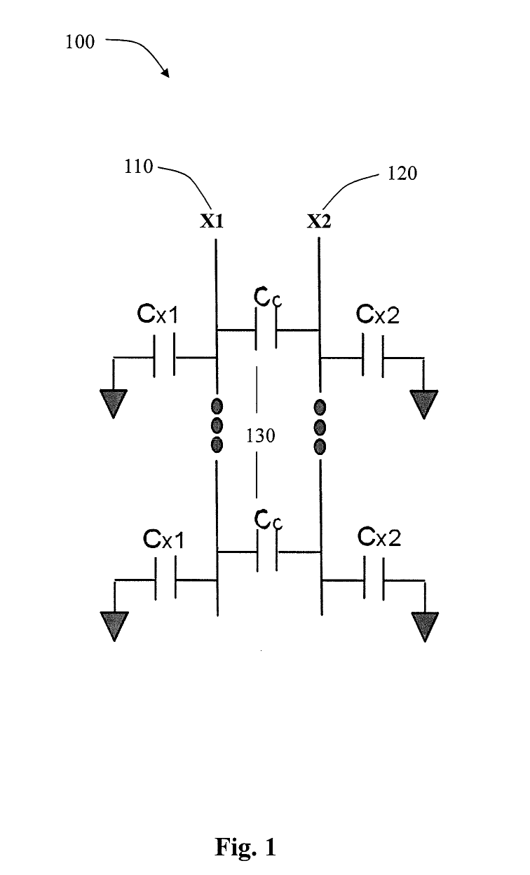

FIG. 1 is a capacitive coupling boost capacitor. There are two coupling lines in the layout 100, X1 110 and X2 120. Capacitor Cc 130 is used as a negative boost capacitor. X1 110 and X2 120 run over a bit-cell and their run length is increased with the number of rows. Total coupling capacitance between X1 110 and X2 120, and thereby the negative boost capacitance, increases with the number of rows in proportion to increased bit-line capacitance. This makes it possible to maintain the ratio between negative boost capacitance and bit-line capacitance to a value that ensures consistent negative level over a wide row range.

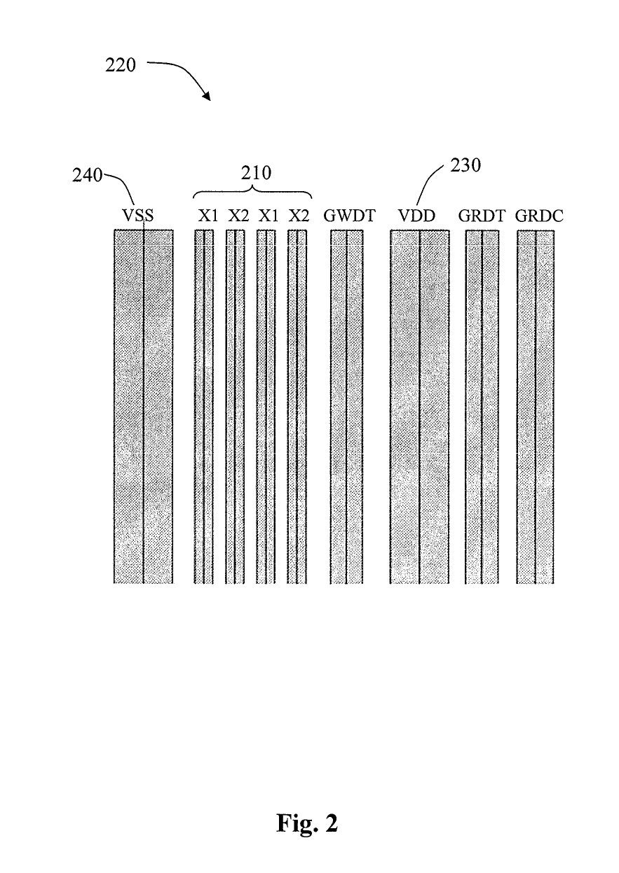

FIG. 2 is a layout implementation of a capacitive coupling boost capacitor. The implementation 200 shows placement of coupling metal lines 210 over a memory cell array 220. For example, the X1 and X2 lines are routed over CMUX2 IO X pitch. In a typical SRAM bit-cell array bit-lines and word-lines are routed orthogonally. Word-lines are also routed one metal layer above the bit-lines. For example, if bit-lines are in M1, word-lines will be in M2. Power and Signal global lines are routed perpendicular to word-lines in further upper metal level (M3). X1 and X2 lines are routed in the upper metal level (in the example being used here, M3), which makes orientation of X1 and X2 lines similar to the bit-lines. As the run length of bit-lines increases with an increased in the number of rows, cross coupling capacitance between X1 and X2 lines also increases. This cross coupling capacitance increase is in proportion to an increment in bit-line capacitance. As mentioned herein, X1 & X2 lines can be shared over X-Pitch of IO circuit, which depends upon size of column multiplexer (CMUX). In the given example implementation, two sets of X1 and X2 lines are routed over CMUX2 IO X pitch. After routing power and global lines in metal 3, enough pitch is left to route an additional set of metal lines to provide coupling without any area overhead. Coupling metal lines are routed with minimum possible width and minimum possible spacing between them to reduce absolute value of capacitance and increase the contribution from cross coupling capacitance to the total capacitance. In 20 nm technology node, if the lines are routed with minimized width and minimized spacing, cross coupling can account for up to almost half of the total capacitance. As shown in FIG. 2, the X1 and X2 signals 210 are placed apart from the other running power and signal lines so as not to increase its absolute capacitance and cross coupling with an undesired signal. In case of higher order multiplexer (CMUX4), X-pitch of 4 columns can be used to route X1 and X2 coupling lines.

For a smaller number of rows in the SRAM, when bitline capacitance is much lesser than common node (WRCOM) capacitance and cross coupling capacitance between metal lines may be insufficient to provide a sufficient amount of boost capacitance, small sized MOS devices may be used. The MOS device can be sized as per the smaller number of rows to counter act common node (WRCOM) capacitance. This causes very less overhead area. As the number of rows increases, cross coupling capacitance and resultant boost capacitance increases. In an embodiment of the invention, MOS device size can be determined as per smaller number of rows (such as less than or equal to 32 rows) and metal lines, to provide cross coupling, are placed in redundant area so that it causes very little area overhead—approximately 1% to 3% based upon instance configuration.

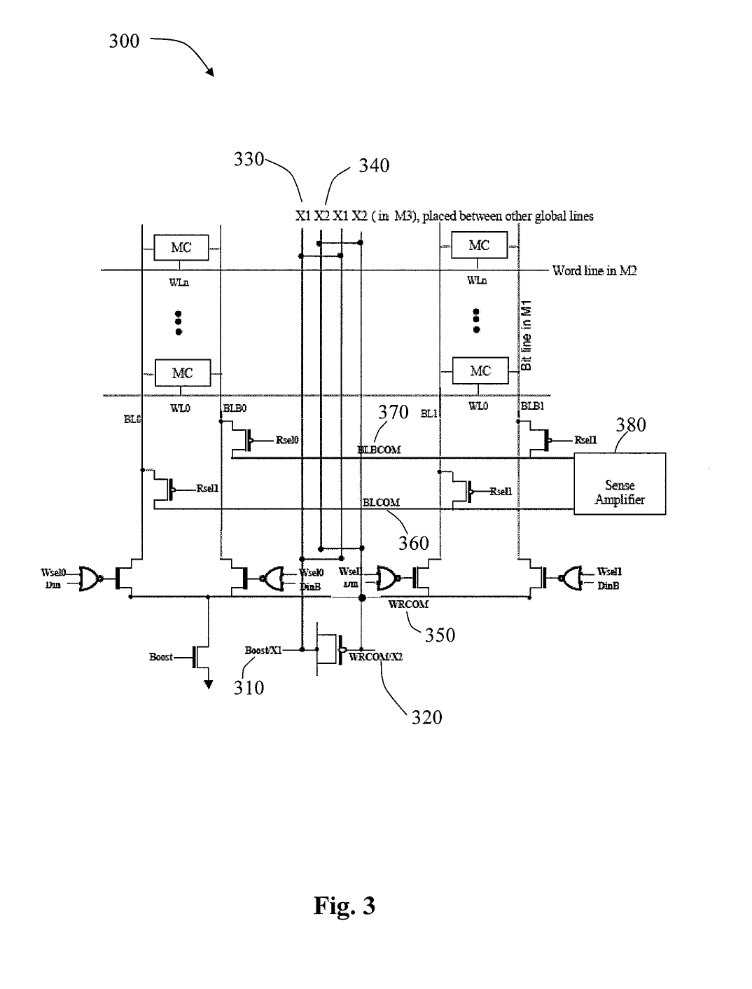

FIG. 3 shows a circuit implementation of a negative boost diagram. In the circuit 300, Bit-line pre-charge devices and boost signal generation logic are not shown but it is understood by those skilled in the art how such elements function. Signal X1&Boost 310, and signal X2&WRCOM 320, are shorted with each other. X1 330 and X2 340 lines are in the upper layer of metals in which global Read/Write bit-line are present. In a 20 nm SRAM bit-cell, this is Metal 3. Placing X1 330 and X2 340 in M3 in this manner does not incur area overhead. Cross coupling between X1 330 and X2 340 is used as negative boost capacitor, which increases with the number of rows in proportion to bit-line capacitance. For reference, CMUX2 IO circuit shown in the implementation 300 can be extended to any number of CMUX IO. Bit-line and Complementary bit-line pairs are coupled to write common node (WRCOM 350) by help of respective write passgate devices. There are a separate set of read passgate devices, a common bit-line (BLCOM) 360 and a common complementary bit-line (BLBCOM) 370, which are coupled to a sense amplifier 380. During a write operation, read passgate device gates are asserted high in order to isolate them from active paths. For a point of reference it is noted that in the FIG. 3, the X1 lines 330 and the Boost/X1 lines 310 are the same line as they are shorted together. Also, the X2 lines 340 and the WRCOM/X2 line 320 are the same line as they are shorted together.

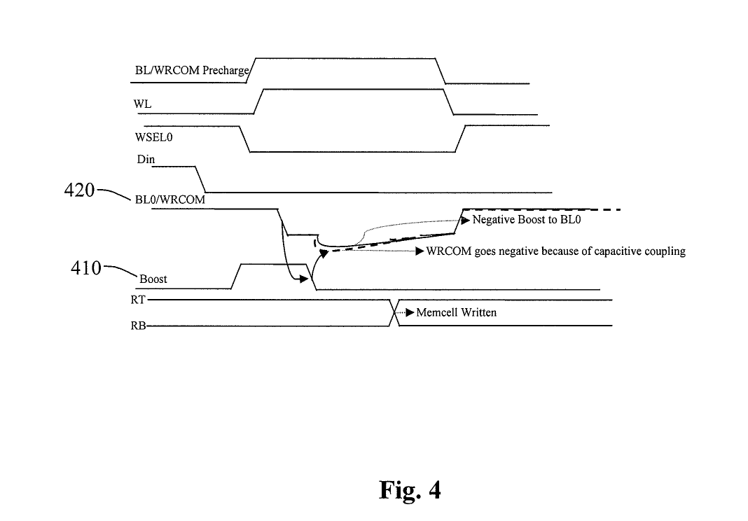

In response to MUX select signal (Wsel0 and Wsel1) and input data (Din and DinB), one of the write pass-gates turn on. FIG. 4 is a timing diagram showing write driver correspondence to bit-line BL0 assertion in response to Wsel0 and Din signal. The BOOST signal 410 is asserted to high to discharge the selected bit-line BL0 and WRCOM node. When BL0 and WRCOM0 420 have been discharged to Vss, the BOOST signal makes transition from high to low and capacitive coupling occurs on a selected bit-line (BL0) and WRCOM line with boost capacitor, and the level of WRCOM and BL0, which are discharged to Vss, drops below Vss.

The BOOST signal can be generated by use a variety of circuits. For example, the BOOST signal can be generated by WRCOM or bit-line discharge detection in another. Also, the BOOST signal could be generated by detection of discharge of a reference bit-line. Consistent with the invention, using a cross coupling capacitor as a boost capacitor is a way to generate control signals to generate the BOOST signal.

If there is not an X pitch remaining to route additional metal lines, the coupling between existing routed signals, which are not used during a write operation, can be used to provide coupling. For example, capacitive coupling between global read bit-line pair (GRDT and GRDC, as shown in FIG. 2) can be used to implement negative boost capacitance. It is understood, that in FIG. 2, only two sets of coupling lines (X1 and X2) are shown for reference. Based upon boost capacitance requirements, and available space, less or more than two sets of coupling lines may be used. The width and spacing between coupling lines (X1 and X2) can be also modified as desired to precisely control amount of negative boost.

Shrinking technology is forcing reduction in metal line width which gives a benefit of reduced capacitance. At the same time, however, in order to maintain reasonable resistivity, its thickness needs to be also increased. As a result, the impact of cross coupling capacitance (capacitance within the same metal layers) is increasing with shrinking feature sizes. In an embodiment of the invention, it is proposed to utilize this cross coupling capacitance so that the effectiveness of the proposed circuit will increase with smaller feature sizes. Further, the structure and methods of the invention disclosed herein can be helped with the use of MOSFETS, MISFETS, FINFETS and other field effect, and similar, devices.

It is understood that the methods and systems provide herein may be used to provide negative or positive coupling to other global lines in the memory architecture. These boosts may enhance memory performance such as access, setup time, etc.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. A method of producing capacitive coupling in a memory architecture, said memory architecture comprising a plurality of bitcell rows and bitcell columns and at least one layer, said method comprising:
placing at least one pair of metal lines over the rows of bitcells in an upper metal layer of the memory architecture wherein the metal lines produce a negative boost to bitlines in the memory architecture.

2. The method of claim 1, wherein said memory architecture is a SRAM architecture.

3. The method of claim 2, wherein said step of placing at least one pair of metal lines produces coupling with at least one other global line in the SRAM architecture.

4. The method of claim 2, wherein said metal lines are placed in a redundant area of an upper layer of the SRAM architecture.

5. The method of claim 3, wherein said step of placing at least one pair of metal lines produces coupling with at least one other global line in the SRAM architecture.

6. The method of claim 3, further comprising:
field effect devices scaled to the number of rows in the SRAM architecture when there are a small number of rows.

7. The method of claim 1, which is used to provide negative or positive coupling to other global lines in the architecture.

8. The method of claim 4, which is used to provide negative or positive coupling to other global lines in the architecture.

9. A system of producing capacitive coupling in a memory architecture, said system comprising:
a MUX select signal;
an input data signal;
a BOOST signal;
a selected bitline;
a write common node; and
a boost capacitor;
wherein a write passgate turns on in response to the MUX select and input data signal, the boost signal is asserted high to discharge the bitline and write common node, and when it is determined that the bitline and write common node have been discharged to a Vss level, the boost signal is asserted low to produce capacitive coupling on the selected bitline and write common node with the boost capacitor.

10. The method of claim 9, wherein said memory architecture is a SRAM architecture.

11. The system of claim 9, further wherein the selected bitline and write common node go below Vss.

12. The system of claim 10, further wherein the selected bitline and write common node go below Vss.
